(19) United States
(12) Patent Application Publication
(10) Pub. No.: US 2012/0083120 A1
(43) Pub. Date: Apr. 5, 2012

(54) SUBSTRATE PROCESSING APPARATUS AND METHOD OF MANUFACTURING A SEMICONDUCTOR DEVICE

(75) Inventors: Takayuki NAKADA, Toyama-shi (JP); Tomoshi TANIYAMA, Toyama-shi (JP)

(73) Assignee: HITACHI KOKUSAI ELECTRIC INC., Tokyo (JP)

(21) Appl. No.: 13/210,978

(22) Filed: Aug. 16, 2011

(30) Foreign Application Priority Data
Oct. 1, 2010 (JP) 2010-223418

(51) Int. Cl. H01L 21/302; H01L 21/3065

(52) U.S. Cl. 438/689; 156/345.31; 257/E21.214

(57) ABSTRACT

A substrate processing apparatus includes a processing chamber in which a substrate is processed, a substrate holder configured to be loaded into and unloaded from the processing chamber while holding the substrate, a transfer chamber in which a charging operation for causing the substrate holder to hold an unprocessed substrate and a discharging operation for taking out a processed substrate from the substrate holder are performed, and a cleaning unit configured to blow clean air into the transfer chamber. The transfer chamber has a polygonal plan-view shape and includes corner areas. The cleaning unit is arranged in one of the corner areas of the transfer chamber.

### CROSS-REFERENCE TO RELATED APPLICATION

This application is based upon and claims the benefit of priority from Japanese Patent Application No. 2010-223418, filed on Oct. 1, 2010, the entire contents of which are incorporated herein by reference.

### TECHNICAL FIELD

The present disclosure relates to a substrate processing apparatus and a method of manufacturing a semiconductor device.

### BACKGROUND

In general, a vertical substrate processing apparatus for use in a semiconductor device includes a transfer chamber arranged below a wafer processing chamber. During the manufacturing process an operation of transferring unprocessed wafers to a substrate holder (or a boat) to be loaded into the processing chamber (which is called a wafer charging operation) and an operation of transferring processed wafers from the substrate holder unloaded from the processing chamber (which is called a wafer discharging operation) are performed. Within the transfer chamber, airflow containing clean air is generated to keep the wafers from being contaminated by particles and to cool the hot processed wafers unloaded from the processing chamber to a predetermined temperature. The airflow is generated by installing a cleaning unit with a filter and a blower along one sidewall of the transfer chamber and blowing clean air from the cleaning unit into the transfer chamber (see, e.g., JP2002-175999A)

However, the airflow generated within the transfer chamber of the above substrate processing apparatus comes from a cleaning unit installed along one sidewall of the transfer chamber which causes the airflow to go from side-to-side. This poses the following problems mentioned below.

One of the problems is that, when the airflow goes from side-to-side, the air tends to stay in corner areas of the transfer chamber. If the air does not move and stays within the transfer chamber, this may cause particle contamination of the wafers. If heat-radiating members such as just-processed wafers exist within the transfer chamber, particles may possibly be generated from the wafer transfer machine due to the heat of the heat-radiating members. For this reason, it is very important to prevent the occurrence of stagnant air that does not move and that stays within the transfer chamber, because the particles may stay in the chamber and contaminate the wafers.

Another problem resides in that the fact that the side-to-side air flow makes it difficult to reduce the installation space of the substrate processing apparatus. This is because the width of the substrate processing apparatus is increased in proportion to the size of the cleaning unit installed along the sidewall of the transfer chamber. In particular, this may become a big problem if the diameter of the wafers is increased (e.g., from 300 mm to 450 mm).

### SUMMARY

The present disclosure provides some embodiments of a substrate processing apparatus capable of reliably generating airflow within a transfer chamber by preventing air from staying within the transfer chamber and capable of reducing the installation space needed for the apparatus by efficiently using the internal space of the transfer chamber.

According to one embodiment of the present disclosure, a substrate processing apparatus includes a processing chamber in which a substrate is processed; a substrate holder configured to be loaded into and unloaded from the processing chamber while holding the substrate; a transfer chamber in which a charging operation for causing the substrate holder to hold an unprocessed substrate and a discharging operation for taking out a processed substrate from the substrate holder are performed; and a cleaning unit configured to blow clean air into the transfer chamber, wherein the transfer chamber has a polygonal plan-view shape and the cleaning unit is arranged in a first corner area of the transfer chamber.

According to another embodiment of the present disclosure, a method of manufacturing a semiconductor device includes a pre-loading transfer operation of performing, within a transfer chamber in communication with a processing chamber, a charging operation by which a substrate holder is caused to hold an unprocessed substrate before the substrate holder is loaded into the processing chamber; loading the substrate holder holding the unprocessed substrate from the transfer chamber into the processing chamber; processing the substrate held by the substrate holder loaded into the processing chamber; unloading the substrate holder holding a processed substrate from the processing chamber into the transfer chamber; and a post-loading transfer operation of performing a discharging operation by which the processed substrate held by the substrate holder unloaded from the processing chamber is taken out from the substrate holder, wherein the transfer chamber is configured to have a polygonal plan-view shape, a cleaning unit is arranged in a corner area of the transfer chamber, and clean air is blown into the transfer chamber by the cleaning unit during at least one of the pre-loading transfer operation and the post-loading transfer operation.

### BRIEF DESCRIPTION OF THE DRAWINGS

FIG. 1 is a perspective view showing a schematic configuration example of a substrate processing apparatus according to one embodiment of the present disclosure.

FIG. 2 is a vertical section view showing a configuration example of a processing furnace employed in the substrate processing apparatus.

FIG. 3 is a perspective view showing a configuration example of a transfer chamber employed in the substrate processing apparatus.

FIG. 4 is a plan view schematically showing a boat exchange device employed in the substrate processing apparatus.

FIG. 5 is a perspective view schematically illustrating airflow formation within a transfer chamber of a conventional configuration as a comparative example of the present disclosure.

FIG. 6A is a plan view showing an example of airflow formation within a transfer chamber of the substrate processing apparatus according to one embodiment of the present disclosure.

FIG. 6B is a plan view showing an example of airflow formation within a transfer chamber of a conventional substrate processing apparatus as a comparative example of the present disclosure.

FIG. 7 is a plan view schematically showing airflow in air circulation routes above the transfer chamber of the substrate processing apparatus according to one embodiment of the present disclosure.

FIG. 8A is a plan view showing an example of airflow formation within a transfer chamber of a substrate processing apparatus according to another embodiment of the present disclosure.

FIG. 8B is a plan view showing an example of airflow formation.

FIG. 9 is a plan view showing an example of airflow formation within a transfer chamber of a substrate processing apparatus according to a further embodiment of the present disclosure.

### DETAILED DESCRIPTION

### One Embodiment of the Present Disclosure

One embodiment of the present disclosure will now be described in detail with reference to the drawings.

### (1) Overview of Substrate Processing Apparatus

First, a brief description will be made giving an overview of a substrate processing apparatus according to one embodiment of the present disclosure.

The substrate processing apparatus described in the present embodiment is usable in a semiconductor device manufacturing process and is configured to process substrates accommodated within a processing chamber by heating the substrates with a heater. More specifically, the substrate processing apparatus of the present embodiment is a vertical substrate processing apparatus configured to simultaneously process a plurality of substrates stacked one above another with specified gaps left therebetween.

Examples of the substrates to be processed by the substrate processing apparatus include semiconductor wafer substrates (hereinafter, simply referred to as “wafer”) each incorporating semiconductor integrated circuit devices (semiconductor devices). Examples of the process to be performed by the substrate processing apparatus include oxidizing, diffusing, reflowing or annealing for carrier activation or planarization after ion implantation, and film-forming through thermal CVD (Chemical Vapor Deposition) reaction.

### (2) Schematic Configuration of Substrate Processing Apparatus

The following is a description of a schematic configuration of an example of a substrate processing apparatus according to one embodiment of the present disclosure.

### (Substrate Processing Apparatus As a Whole)

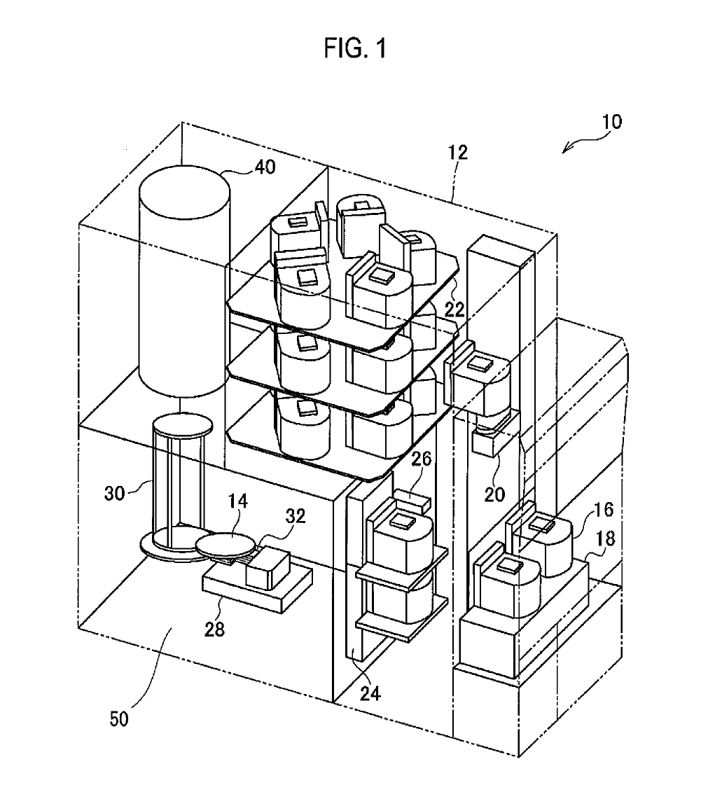

FIG. 1 is a perspective view showing a configuration example of a substrate processing apparatus according to one embodiment of the present disclosure. The substrate processing apparatus 10 includes a housing 12 accommodating therein certain major parts such as a processing furnace 40. A pod stage 18 is arranged in the front area of the housing 12. Hoops (hereinafter referred to as “pods”) 16 act as a substrate receiver for receiving wafers 14 and are mounted on the pod stage 18. Each of the pods 16 is configured to store therein, e.g., twenty five wafers 14, and is mounted on the pod stage 18 with a lid (not shown) thereof kept closed. That is to say, each of the pods 16 is used as a wafer carrier in the substrate processing apparatus 10.

In the internal front area of the housing 12, a pod conveying device 20 is arranged in an opposing relationship with the pod stage 18. In the vicinity of the pod conveying device 20, there are arranged a pod rack 22, a pod opener 24 and a substrate number detector 26.

The pod conveying device 20 is configured to convey the pod 16 among the pod stage 18, the pod rack 22 and the pod opener 24.

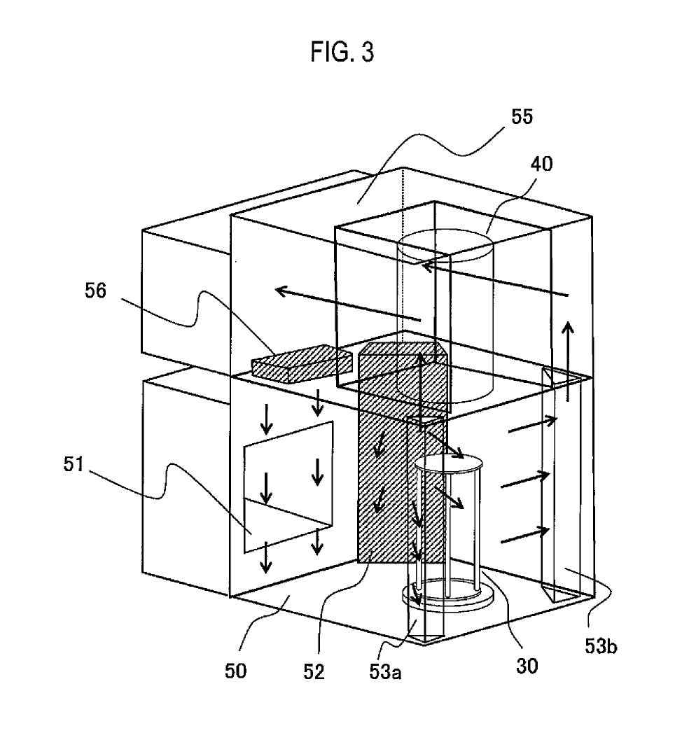

The pod rack 22 is arranged above the pod opener 24 and is configured to hold a plurality of pods 16 mounted thereon. The pod rack 22 may be a so-called rotary rack having a plurality of rack panels. The rotary rack is rotated pitch by pitch in one direction by an intermittent rotary drive device (not shown) such as a motor. However, the rotation function is not essential in the pod rack 22. In the vicinity of the pod rack 22, a cleaning unit 52 (not shown in FIG. 1, but will be shown in FIG. 3) having a supply fan and a dust-proof filter may be provided so that clean air as a purified atmospheric gas can be fed from the cleaning unit 52 to the pod rack 22.

The pod opener 24 is configured to open the lid of the pod 16. The substrate number detector 26 is arranged adjacent to the pod opener 24 and is configured to detect the number of the wafers 14 held within the pod 16 with the lid thereof opened.

At the rear side of the pod opener 24 within the housing 12, there is provided a transfer chamber 50 as a single room defined within the housing 12. The details of the transfer chamber 50 will be described later.

A substrate transfer machine 28 and a boat 30 as a substrate holder are arranged within the transfer chamber 50.

The substrate transfer machine 28 includes an arm (tweezers) 32 capable of taking out, e.g., five wafers 14. The substrate transfer machine 28 is configured to convey the wafers 14 between the pod 16, which is placed on the pod opener 24, and the boat 30 by rotationally driving the arm 32 up and down with a drive means not shown in the drawings.

The boat 30 is configured to hold a plurality of (e.g., about fifty to one hundred fifty) vertically stacked wafers 14 in a horizontal position with their centers aligned with one another and with specified vertical gaps left therebetween. The boat 30 holding the wafers 14 can be moved up and down by a boat elevator as a lift mechanism not shown in the drawings.

A processing furnace 40 is arranged in the rear upper area within the housing 12 above the transfer chamber 50. The boat 30 charged with the wafers 14 can be loaded into the processing furnace 40 from below.

### (Processing Furnace)

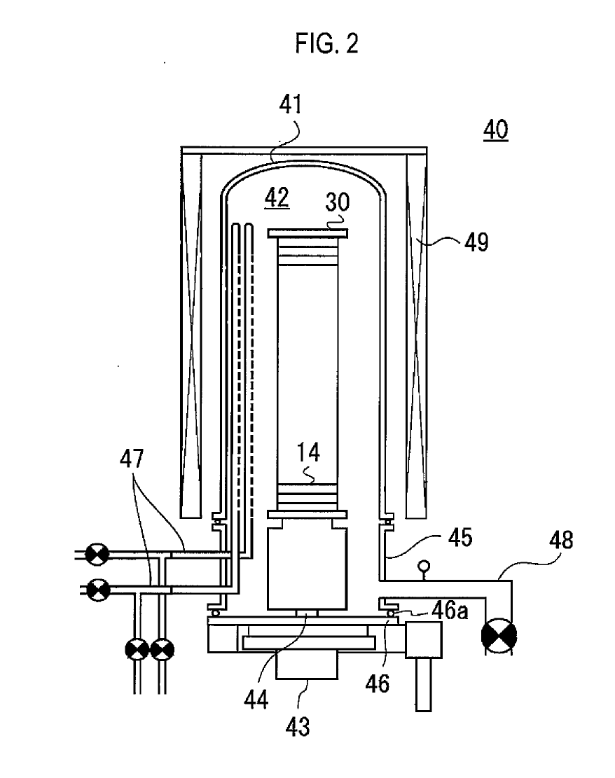

Next, a brief description will be made of the processing furnace 40. FIG. 2 is a vertical section view showing a configuration example of the processing furnace employed in the substrate processing apparatus according to one embodiment of the present disclosure.

The processing furnace 40 includes a reaction tube 41 made of a heat-resistant non-metallic material, e.g., quartz (SiO₂) or silicon carbide (SiC). The reaction tube 41 has a cylindrical shape with a closed top end and an open bottom end.

A processing chamber 42 is defined within the reaction tube 41. The boat 30 as a substrate holder is inserted into the processing chamber 42 from below. The wafers 14 horizontally held by the boat 30 are accommodated within the processing chamber 42 in a vertically stacked orientation. Upon rotating a rotation shaft 44 with a rotating mechanism 43, the boat 30 accommodated within the processing chamber 42 is rotated while the inside of the processing chamber 42 is kept air-tight and the wafers 14 mounted thereon.

Below the reaction tube 41, a manifold 45 is arranged in a concentric relationship with the reaction tube 41. The manifold 45 is made of a metallic material, e.g., stainless steel, and has a cylindrical shape with open top and bottom ends. The reaction tube 41 is vertically supported at its bottom end by the manifold 45. In other words, the processing furnace 40 is configured by vertically installing the reaction tube 41 defining the processing chamber 42 on the manifold 45.

The bottom end of the manifold 45 is hermetically sealed by a seal cap 46 when a boat elevator (not shown) is moved up. A sealing member 46a such as an O-ring for keeping the inside of the processing chamber 42 air-tight is provided between the bottom end of the manifold 45 and the seal cap 46.

Gas inlet pipes 47 for introducing therethrough a source gas and a purge gas into the processing chamber 42 and an exhaust pipe 48 for discharging therethrough a gas from the inside of the processing chamber 42 are connected to the manifold 45.

Around the outer periphery of the reaction tube 41, a heater unit 49 as a heating means (or a heating mechanism) is arranged in a concentric relationship with the reaction tube 41. The heater unit 49 is configured to heat the inside of the processing chamber 42 such that the inside of the processing chamber 42 has a uniform temperature over the entire area thereof or at a specified temperature distribution.

### (3) Substrate Processing Process

Next, a description will be made of an operation sequence when the substrate processing apparatus 10 of the present embodiment is used to process the wafers 14 in a semiconductor device manufacturing process.

### (Wafer Supply Step)

In order to process the wafers 14 with the substrate processing apparatus 10, the pod 16 accommodating a plurality of wafers 14 therein is first mounted on the pod stage 18. Then, the pod 16 is transferred from the pod stage 18 to the pod rack 22 through the use of the pod conveying device 20. The pod 16 mounted on the pod rack 22 is conveyed to the pod opener 24 by the pod conveying device 20. Thereafter, the lid of the pod 16 is opened by the pod opener 24. The number of the wafers 14 accommodated within the pod 16 is detected by the substrate number detector 26.

### (Pre-Loading Transfer Step)

After the lid of the pod 16 is opened by the pod opener 24, the substrate transfer machine 28 arranged within the transfer chamber 50 takes out the wafers 14 from the pod 16. Then, the unprocessed wafers 14 taken out from the pod 16 are transferred to the boat 30 positioned within the transfer chamber 50 together with the substrate transfer machine 28. In other words, the substrate transfer machine 28 performs within the transfer chamber 50 a wafer charging operation by which the unprocessed wafers 14 not yet loaded into the processing chamber 42 are charged to the boat 30. Thus, the boat 30 holds the wafers 14 in a vertically stacked orientation with gaps left therebetween. The number of the wafers 14 held in a stacked condition by the boat 30 and subjected to batch processing may be, e.g., from twenty five to one hundred. This makes it possible to enhance productivity.

### (Loading Step)

After the wafer charging operation, the boat elevator is moved up to thereby load the boat 30 holding the unprocessed wafers 14 into the processing chamber 42 (which is called a boat loading operation). In other words, the boat elevator is operated to load the boat 30 holding the unprocessed wafers 14 from the transfer chamber 50 into the processing chamber 42. This causes the seal cap 46 to seal the bottom end of the manifold 45 with the sealing member 46a interposed therebetween.

### (Processing Step)

After the boat loading operation, the unprocessed wafers 14 held by the boat 30 loaded into the processing chamber 42 are subjected to a specified processing. More specifically, when a film formation processing is performed by, e.g., thermal CVD reaction, a gas is exhausted through the exhaust pipe 48 to maintain the inside of the processing chamber 42 at a desired pressure (or a desired vacuum degree). Then, the inside of the processing chamber 42 is heated by the heater unit 49 and the rotating mechanism 43 is operated to rotate the boat 30 and hence the wafers 14. The wafers 14 continue to rotate until the boat 30 holding the wafers 14 is unloaded. In addition, a source gas or a purge gas is supplied into the processing chamber 42 through the gas inlet pipes 47. Thus, thin films are formed on the surfaces of the unprocessed wafers 14 held in the boat 30 by thermal decomposition reaction or chemical reaction.

After the thin films are formed on the surfaces of the wafers 14, the heating operation of the heater unit 49 is stopped to allow the processed wafers 14 to be cooled to a specified temperature. If a predetermined time lapses, the supply of the source gas or the purge gas into the processing chamber 42 is stopped and the supply of an inert gas into the processing chamber 42 is started. In this manner, the gas existing within the processing chamber 42 is substituted by the inert gas. The internal pressure of the processing chamber 42 is restored to atmospheric pressure.

### (Unloading Step)

Thereafter, the boat elevator is moved down to lower the seal cap 46 and open the bottom end of the manifold 45 and to unload the boat 30 holding the processed wafers 14 from the bottom end of the manifold 45 to the outside of the processing chamber 42 (which is called a boat unloading operation).

In other words, the boat elevator is operated to unload the boat 30 holding the processed wafers 14 from the inside of the processing chamber 42 into the transfer chamber 50. Then, the boat 30 waits in a specified position until all the wafers 14 held in the boat 30 is cooled down.

### (Post-Loading Transfer Step)

After the wafers 14 of the waiting boat 30 is cooled down to a specified temperature (e.g., room temperature or so), the substrate transfer machine 28 arranged within the transfer chamber 50 discharges the wafers 14 from the boat 30.

Then, the processed wafers 14 discharged from the boat 30 are conveyed to and accommodated within the empty pod 16 mounted on the pod opener 24. In other words, the substrate transfer machine 28 performs within the transfer chamber 50 a wafer discharging operation by which the processed wafers 14 held in the boat 30 unloaded from the inside of the processing chamber 42 are taken out from the boat 30 and transferred to the pod 16.

Thereafter, the pod conveying device 20 conveys the pod 16 accommodating the processed wafers 14 onto the pod rack 22 or the pod stage 18.

In this manner, a series of processing operations in the substrate processing process performed by the substrate processing apparatus 10 of the present embodiment come to an end.

### (4) Configuration of Transfer Chamber

Next, the configuration of the inside of the transfer chamber 50, one features of the substrate processing apparatus 10 according to the present embodiment, will be described in detail by way of example. A transfer chamber of a so-called two-boat-type substrate processing apparatus in which two boats 30 are alternately loaded into and unloaded from a processing chamber 42 in order to increase throughput will be taken as an example in the following description.

### (Transfer Chamber)

FIG. 3 is a transparent perspective view showing a configuration example of a transfer chamber employed in the substrate processing apparatus according to one embodiment of the present disclosure.

As described above, the substrate processing apparatus 10 is provided with the transfer chamber 50 within which to perform the wafer charging operation for causing the unprocessed wafers 14 to be held in the boat 30 and the wafer discharging operation for taking out the processed wafers 14 from the boat 30. The transfer chamber 50 is a single room of rectangular plan-view shape defined by a ceiling, a floor and four sidewalls. The transfer chamber 50 shall not be limited to the rectangular plan-view shape but may be configured to have polygonal plan-view shapes (e.g., a triangular plan-view shape or a pentagonal plan-view shape). In this regard, the transfer chamber 50 need not be composed of a load-lock chamber or a nitrogen purge box and may be kept in an ambient air atmosphere.

A wafer entry and exit gate 51 as a substrate receiving communication gate is formed in the sidewall of the transfer chamber 50 near the pod opener 24 so that the wafers 14 can be conveyed through the wafer entry and exit gate 51 between the pod 16 placed on the pod opener 24 and the boat 30 positioned within the transfer chamber 50. An opening (not shown) communicating with the inside of the processing chamber 42 is formed in the ceiling of the transfer chamber 50 having such a shape and size as to permit passage of the boat 30 holding the wafers 14.

In addition to the substrate transfer machine 28, the boat 30 and the boat elevator (not shown), a cleaning unit 52 and exhaust units 53a and 53b are arranged within the transfer chamber 50.

(Cleaning unit)

The cleaning unit 52 arranged within the transfer chamber 50 is configured to blow a clean air into the transfer chamber 50. To this end, the cleaning unit 52 includes a filter formed of, e.g., an ULPA (Ultra Low Penetration Air) filter, and a blower electrically driven to blow an air.

For the reasons mentioned later, the cleaning unit 52 of this configuration is arranged in a corner area within the transfer chamber 50 having a polygonal plan-view shape.

### (Exhaust Unit)

The exhaust units 53a and 53b arranged within the transfer chamber 50 are configured to exhaust an air existing within the transfer chamber 50 (including not only a clean air but also a particle-containing air) to the outside of the transfer chamber 50. To this end, each of the exhaust units 53a and 53b includes a duct extending from the inside of the transfer chamber 50 to the outside thereof and an electric exhaust fan installed within the duct.

For the reasons set forth later, the exhaust units 53a and 53b of this configuration are arranged in other corner areas within the transfer chamber 50 than the corner area where the cleaning unit 52 is arranged.

### (Airflow Circulation Path)

The processing furnace 40 is arranged above the transfer chamber 50 having the afore-mentioned internal configuration. However, the internal space of the housing 12 existing above the transfer chamber 50 is not fully occupied by the processing furnace 40. An airflow circulation path 55 is formed in the spatial area around the processing furnace 40.

The airflow circulation path 55 is provided to resupply the air exhausted from the inside of the transfer chamber 50 into the transfer chamber 50 through the cleaning unit 52. More specifically, the airflow circulation path 55 defines an air route along which the air exhausted from the inside of the transfer chamber 50 by the exhaust units 53a and 53b flows toward an air inlet port of the cleaning unit 52. The airflow circulation path 55 is configured to resupply clean air into the transfer chamber 50 through the cleaning unit 52 by allowing the cleaning unit 52 to draw the air from the airflow circulation path 55.

An air damper not shown in the drawings is provided in the air route defined by the airflow circulation path 55. The air damper is configured to control the flow rate of the air flowing through the airflow circulation path 55. More specifically, the air damper may be configured using a well-known flow rate control mechanism such as a butterfly valve or a needle mechanism. It is however preferred that the air damper has a function of automatically controlling a flow rate and be controllable in conjunction with the cleaning unit 52.

A second cleaning unit 56 may be provided above the transfer chamber 50. The second cleaning unit 56 is configured to generate a local down-stream airflow of the clean air near the wafer entry and exit gate 51. More specifically, just like the cleaning unit 52, the second cleaning unit 56 may be configured to include a filter such as an ULPA filter and a blower. If the second cleaning unit 56 is employed, the airflow circulation path 55 allows both the cleaning unit 52 and the second cleaning unit 56 to draw the air exhausted from the transfer chamber 50 so that a clean air can be resupplied into the transfer chamber 50.

### (Boat Exchange Device)

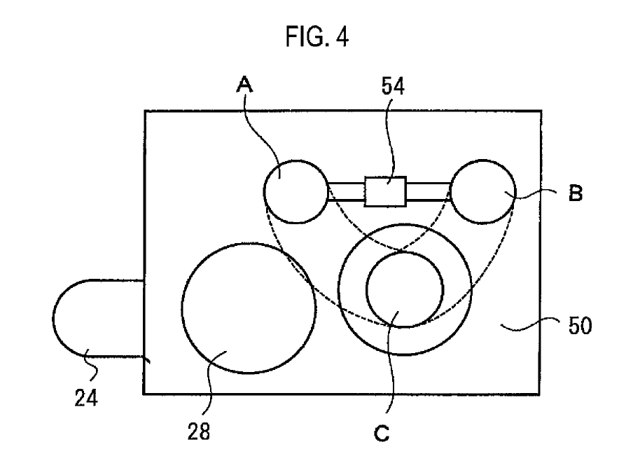

FIG. 4 is a plan view schematically showing a boat exchange device employed in the substrate processing apparatus according to one embodiment of the present disclosure.

In the two-boat-type substrate processing apparatus, a boat exchange device 54 is provided within the transfer chamber 50 to alternately load and unload two boats 30 into and from the processing chamber 42. The operation of the boat exchange device 54 within the transfer chamber 50 will now be described with reference to FIG. 4.

Within the transfer chamber 50, each of the boats 30 is moved by a swing arm of the boat exchange device 54 while tracing an arc-shaped trajectory. Each of the boats 30 can take three positions. In FIG. 4, the left end of an arc is a wafer transfer position A where the wafers are transferred to one of the boats 30 by the substrate transfer machine 28, the right end of the arc is a boat cooling position B, and the center of the arc is a boat loading/unloading position C where one of the boats 30 is loaded into and unloaded from the processing chamber 42.

The boat exchange device 54 works as follows. Two empty boats 30 are put in the positions A and B in advance. The wafers taken out from the pod 16 and notch-aligned by a notch alignment machine (not shown) are charged to the boat 30 placed in the position A. Then, the boat 30 placed in the position A and filled with the notch-aligned wafers is conveyed to the position C by the swing arm of the boat exchange device 54. The boat 30 conveyed to the position C is loaded into the processing chamber 42 where the wafers are subjected to a specified processing. While the wafers are processed within the processing chamber 42, the empty boat 30 placed in the position B is conveyed to the position A by the swing arm. The wafers not yet notch-aligned are taken out from the pod 16 and are notch-aligned by the notch alignment machine. The notch-aligned wafers are transferred to and filled in the boat 30 placed in the position A. Subsequently, operations (a) through (d) are repeated as follows.

(a) Once the processing performed within the processing chamber 42 is finished, the boat 30 holding the processed wafers is unloaded from the processing chamber 42 and lowered to the position C. Then, the boat 30 is conveyed to the position B by the swing arm and cooled.

(b) While the cooling is underway, the boat 30 filled with the notch-aligned wafers and placed in the position A is moved to the position C by the swing arm and then loaded into the processing chamber 42 where the notch-aligned wafers are subjected to a specified processing.

(c) While the processing is performed within the processing chamber 42, the boat 30 cooled in the position B is conveyed to the position A by the swing arm. In the position A, the processed wafers are discharged from the boat 30 and returned into the pod 16.

(d) The boat 30 emptied by taking out the processed wafers is charged with the notch-aligned wafers freshly taken out from the pod 16. Thus, the empty boat 30 is filled with the unprocessed wafers.

### (5) Formation of Airflow in Transfer Chamber

Next, airflow (flow of clean air) formed within the transfer chamber 50 of the above configuration will be described in detail.

### COMPARATIVE EXAMPLE

Airflow formation in a conventional configuration as a comparative example of the present disclosure will be described prior to describing airflow formation within the transfer chamber 50 of the present embodiment.

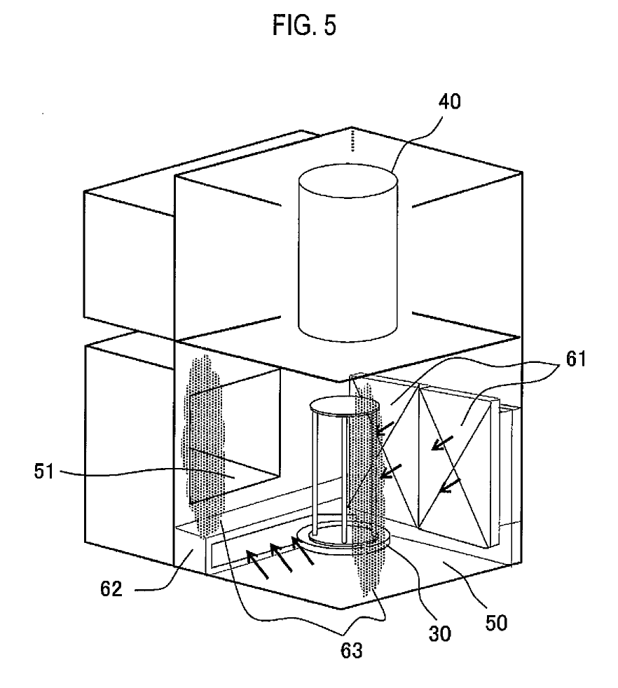

FIG. 5 is a perspective view schematically illustrating airflow formation within a transfer chamber of conventional configuration as a comparative example of the present disclosure.

In the conventional substrate processing apparatus, the cleaning unit 61 including the filter and the blower is arranged within the transfer chamber 50 to extend along one sidewall of the transfer chamber 50. In the lower portion of the sidewall of the transfer chamber 50 on which the wafer entry and exit gate 51 is formed, there is provided a circulation path 62 through which the air existing within the transfer chamber 50 is resupplied into the transfer chamber 50 by the cleaning unit 61. With this configuration, the airflow formed within the transfer chamber 50 flows from side-to-side from the cleaning unit 61.

Since the airflow formed in the conventional configuration flows from side-to-side, the air tends to stay in the corner areas 63 within the transfer chamber 50. In particular, the air that does not move and stays in the corner in the vicinity of the wafer entry and exit gate 51 may cause of particle contamination of the wafers conveyed through the wafer entry and exit gate 51. It is therefore necessary to prevent the air from not moving within the transfer chamber 50.

When forming the airflow in the conventional configuration, the air is circulated (resupplied) using a limited space within the transfer chamber 50. For this reason, it becomes difficult to secure a sufficient installation space for the cleaning unit 61 and the circulation path 62, which makes it difficult to provide a sufficient air flow rate. Thus, the airflow tends to become turbulent. This may cause the air to stay in the corner areas 63 within the transfer chamber 50.

In the meantime, heat-emitting members such as the just-processed wafers exist within the transfer chamber 50. There is a possibility that particles are generated from the wafer transfer machine due to the heat of the heat-emitting members. In the same housing, the non-movement of the air may not cause any problem, e.g., in a space where pod racks are arranged (in a rotary rack installation chamber), but may cause a big problem in the transfer chamber 50 where particles may possibly be generated by heat.

In the conventional configuration for formation of airflow, the cleaning unit 61 is provided along one sidewall of the transfer chamber 50. Thus, an installation space proportional to the size of the cleaning unit 61 needs to be provided in the sidewall of the transfer chamber 50. This makes it difficult to reduce the space for installation of the substrate processing apparatus, especially in the transverse direction of the apparatus. This may lead to a big problem particularly if the diameter of the wafers is increased (e.g., from 300 mm to 450 mm).

### Airflow Formation in the Present Embodiment

After conducting research over and over to find a way to form optimal airflow within the transfer chamber 50 under the circumstances mentioned above, the present inventors have found it desirable to circulate clean air from the corner area of the transfer chamber 50. Based on this finding, the present inventors have conceived a configuration in which, unlike the conventional configuration, the cleaning unit 52 is arranged in the corner area within the transfer chamber 50 to blow a clean air into the transfer chamber 50.

More specifically, as shown in FIG. 3, the cleaning unit 52 is arranged in the corner area within the transfer chamber 50, which is defined by one sidewall having the wafer entry and exit gate 51 and another sidewall adjoining thereto. The exhaust units 53a and 53b are arranged in the corner areas existing at the opposite lateral ends of the sidewall opposed to the sidewall having the wafer entry and exit gate 51. If clean air is blown from the cleaning unit 52 and if an exhaust operation is actively performed by the exhaust units 53a and 53b, flow of clean air (airflow) moving from the cleaning unit 52 toward the exhaust units 53a and 53b are formed within the transfer chamber 50. Since the cleaning unit 52 and the exhaust units 53a and 53b are arranged in the corner areas within the transfer chamber 50, the air predominantly flows in the diagonal direction within the transfer chamber 50. Unlike the side-to-side flow in the conventional configuration, it is hard for the air to stay in the corner areas within the transfer chamber 50.

Assuming that the air would be circulated in the limited space within the transfer chamber 50, it is not always easy to realize the configuration in which the cleaning unit 52 is arranged in the corner area within the transfer chamber 50. This is because it may be difficult to secure a space for defining air circulation routes from the corner areas, which are diagonally opposed to the cleaning unit 52.

Without being bound by the stereotype that the limited space within the transfer chamber 50 should be used to circulate the air, the present inventors have conceived an unprecedented idea that the space above the transfer chamber 50 within the housing 12 is used to form the airflow circulation path 55. With this idea, it is possible to realize the configuration that the cleaning unit 52 is arranged in the corner area within the transfer chamber 50 while defining air circulation routes from the exhaust units 53a and 53b to the cleaning unit 52.

In case where there is further provided the second cleaning unit 56, a local down-stream airflow of the clean air as well as the airflows from the cleaning unit 52 toward the exhaust units 53a and 53b is formed within the transfer chamber 50 in a position facing the wafer entry and exit gate 51.

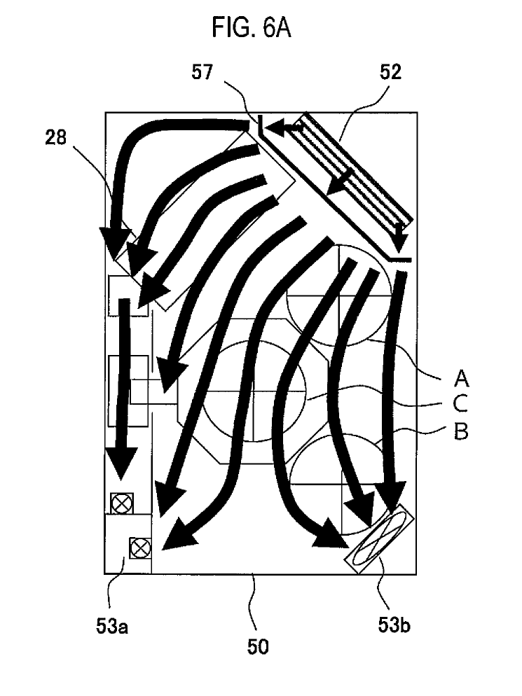

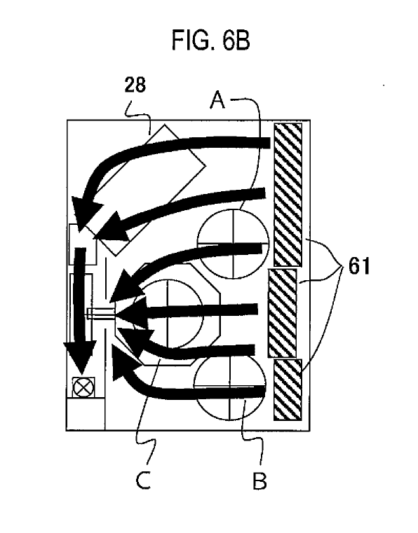

FIG. 6A is a plan view showing an example of airflow formation within the transfer chamber of the present substrate processing apparatus and FIG. 6B is a plan view showing a concrete example of airflow formation within the transfer chamber of the conventional substrate processing apparatus.

In the configuration in which the cleaning unit 52 is arranged in the corner area within the transfer chamber 50 as shown in FIG. 6A, the clean air is blown from the cleaning unit 52 and the exhaust operation is actively performed by the exhaust units 53a and 53b installed in the corner areas facing the cleaning unit 52, whereby airflow is formed between the cleaning unit 52 and the exhaust units 53a and 53b (see arrows in FIG. 6A). In other words, the airflow from one corner area to other corner areas are formed within the transfer chamber 50. Therefore, as compared with the side-to-side flow of air in the conventional configuration, it is difficult for the air to stay in the corner areas within the transfer chamber 50. This makes it possible to form airflow in a reliable manner. Since it is hard for the air to remain still, it is also possible to provide a sufficient cooling effect with respect to the wafers 14.

In particular, if a local down-stream airflow is formed near the wafer entry and exit gate 51 by the second cleaning unit 56, it is possible to prevent the air from staying in the corner area near the wafer entry and exit gate 51 even when the space for installation of an exhaust unit is hard to secure in that corner area. This is quite effective in suppressing particle contamination of the wafers conveyed through the wafer entry and exit gate 51.

In some embodiments, the flow rate in the cleaning unit 52 and the total flow rate in the exhaust units 53a and 53b are balanced so that they can be equal to each other. A result of analysis reveals that well-balanced airflow can be formed by setting the ratio of the flow rate in the cleaning unit 52, the flow rate in one of the exhaust units 53a and the flow rate in the other exhaust unit 53b equal to, e.g., 1:0.5:0.5. The balance of the flow rates is not limited to the example noted above but may be properly determined on a case-by-case basis. This is because the wafer temperature varies with the processing conditions within the processing chamber 42 (e.g., depending on the kinds of films to be formed).

While the cleaning unit 52 arranged in the corner area within the transfer chamber 50 may be used as it stands, in some embodiments an air diffuser 57 for distributing the clean air blown out from the cleaning unit 52 in at least three different directions may be installed at the air discharge side of the cleaning unit 52. The air diffuser 57 may in dome embodiments be provided with vanes for changing the flow direction of the clean air. Examples of the airflow distributed in at least three different directions by the air diffuser 57 include (a) an airflow moving toward the front end of the wafer entry and exit gate 51 and the substrate transfer machine 28, (b) an airflow moving toward the boat elevator and (c) an airflow moving toward the boat exchange device 54. By distributing the airflow in three different directions in this manner, clean air is supplied as airflow (a), (b) and (c) having different roles. Installation of the air diffuser 57 is highly effective in increasing the cleanliness within the transfer chamber 50 (including the cleanliness of the wafers 14).

The configuration described above has a huge advantage in that it is possible not only to eliminate the non-movement of air within the transfer chamber 50 but also to keep the apparatus width as small as possible even when the diameter of the wafers is increased (e.g., from 300 mm to 450 mm).

In the conventional configuration for formation of side to side airflow, as shown in FIG. 6B, a space for installation proportional to the size of the cleaning unit 61 should be provided in an of area of one sidewall of the transfer chamber 50 in order to install the cleaning unit 61. This means that the space within the transfer chamber 50 is not utilized efficiently. In the conventional configuration shown in FIG. 6B, an exhaust fan is arranged at the sidewall opposing the cleaning unit 61.

When the wafers 14 to be processed have a diameter of 300 mm, the conventional configuration for formation of side to side airflow is applicable with no significant problem. However, if the diameter of the wafers 14 is increased to 450 mm, it is extremely difficult to install the cleaning unit 61 in the conventional manner because the installation space available within the transfer chamber 50 becomes quite narrow (gets smaller in the transverse direction of the apparatus).

In contrast, if the cleaning unit 52 is arranged in the corner area within the transfer chamber 50 as in the present embodiment described above, it is apparent in FIG. 6A that airflow can be reliably formed within the transfer chamber 50 even when the wafers 14 have a diameter of 450 mm. This helps reduce the external size of the substrate processing apparatus which would otherwise be increased in proportion to the increase in the diameter of the wafers 14. In other words, the installation of the cleaning unit 52 in the corner area within the transfer chamber 50 makes it possible to efficiently use the space within the transfer chamber 50, thereby keeping the apparatus width as narrow as possible. This also makes it possible to reliably form airflow within the transfer chamber 50, which assists in enhancing the cleanliness within the transfer chamber 50.

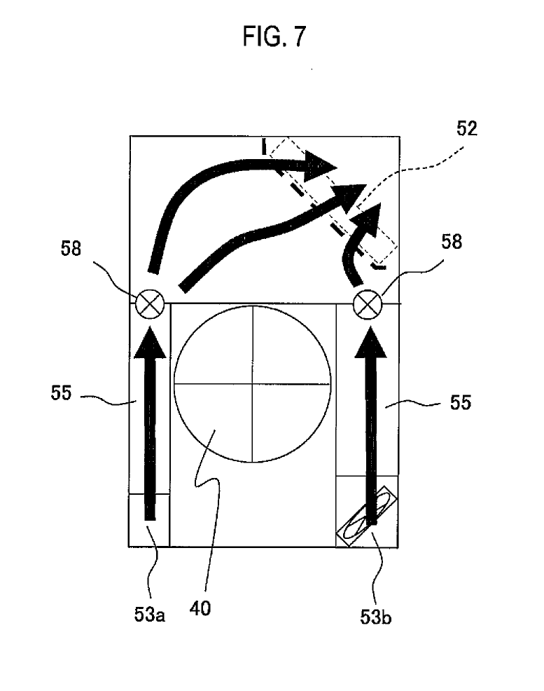

FIG. 7 is a plan view schematically showing airflow formed in air circulation routes above the transfer chamber of the substrate processing apparatus according to one embodiment of the present disclosure.

The air exhausted from the inside of the transfer chamber 50 by the exhaust units 53a and 53b is circulated along the airflow circulation path 55 provided above the transfer chamber 50 and then returned to the cleaning unit 52 or the second cleaning unit 56. If the airflow circulation path 55 is formed using the space existing above the transfer chamber 50 within the housing 12 in this manner, the spatial restriction is relieved as compared with the conventional configuration in which the air is circulated using the limited space within the transfer chamber 50. This makes it possible to increase the flow rate of the circulating air with ease. Even if the exhaust units 53a and 53b are provided in multiple numbers within the transfer chamber 50, it is possible to circulate the air exhausted from the respective exhaust units 53a and 53b (namely, two exhaust units). Accordingly, the air can be circulated at a sufficient flow rate through the cleaning unit 52 or the second cleaning unit 56. This helps prevent the cleaning unit 52 or the second cleaning unit 56 from suffering from shortage in air volume.

Moreover, if the cleaning unit 52 is arranged in the corner area within the transfer chamber 50 and the airflow circulation path 55 is formed using the space existing above the transfer chamber 50 within the housing 12, the area otherwise occupied by the cleaning unit 61 and the circulation path 62 in the conventional configuration become an empty space. As compared with the conventional configuration, this helps increase the degree of freedom in arranging the respective components within the transfer chamber 50.

If air dampers 58 are provided in the air routes defined by the airflow circulation paths 55, the pressure of the clean air within the transfer chamber 50 can be regulated by the control of the flow rates in the air dampers 58. In other words, the pressure of the clean air within the transfer chamber 50 conventionally controlled depending on the flow rate in the cleaning unit 61 can be regulated at the exhaust side by installing the air dampers 58 in the air routes. In this case, it is still more desirable if the flow rates in the air dampers 58 are automatically controlled in conjunction with the operation of the cleaning unit 52 or the second cleaning unit 56. With this configuration, it becomes possible to accurately control the air pressure.

### Effects Offered by the Present Embodiment

The present embodiment may have one or more of the following effects.

(i) With the present embodiment, the cleaning unit 52 is arranged in the corner area within the transfer chamber 50. Therefore, it is difficult for the air to not move within the transfer chamber 50 (particularly in the corner areas within the transfer chamber 50). This makes it possible to form airflow in a reliable manner. In other words, even when the wafers 14 taken out from the processing chamber 42 emit heat, it is possible to prevent the wafers 14 from being contaminated with particles. This is because the present embodiment is configured to prevent air from not moving which may cause the wafers to be contaminated with particles. Moreover, the installation of the cleaning unit 52 in the corner area within the transfer chamber 50 makes it possible to efficiently use the space within the transfer chamber 50 and to readily reduce the installation space of the substrate processing apparatus 10 as compared with the conventional configuration (side-to-side air flow). That is to say, it is possible to realize a configuration that can keep the apparatus width as small as possible even when the wafers 14 have an increased size.

As mentioned above, the present embodiment is configured not to generate the side-to-side airflow as in the conventional configuration but to generate streams of clean air flowing at least in a diagonal direction within the transfer chamber 50 having a rectangular plan-view shape. This makes it possible to prevent air from not moving within the transfer chamber 50 and to prevent the wafers 14 from being contaminated with particles during their transfer. Moreover, it is possible to reliably generate airflow within the transfer chamber 50 while keeping the space of the transfer chamber 50 small.

(ii) With the present embodiment, the exhaust units 53a and 53b are arranged in other corner areas than the corner area where the cleaning unit 52 is arranged. This makes it possible to reliably form airflow within the transfer chamber 50. In other words, since airflow is formed from the cleaning unit 52 toward the exhaust units 53a and 53b, the air predominantly flows in the diagonal direction within the transfer chamber 50. Unlike the side-to side airflow in the conventional configuration, it is difficult of the air to remain in the corner areas within the transfer chamber 50 without moving.

(iii) With the present embodiment, there is provided the air diffuser 57 for distributing the clean air blown out from the cleaning unit 52 in at least three different directions. This makes it possible to supply the clean air in the respective directions to play different roles. The installation of the air diffuser 57 makes it easy to increase the cleanliness within the transfer chamber 50.

(iv) With the present embodiment, the airflow circulation path 55 is formed using the space existing above the transfer chamber 50 within the housing 12. As compared with the conventional configuration in which the air is circulated using the limited space within the transfer chamber 50, this helps prevent the cleaning unit 52 or the second cleaning unit 56 from suffering from a shortage in air volume.

In addition, the air dampers 58 are provided in the air routes defined by the airflow circulation paths 55, whereby the pressure of the clean air within the transfer chamber 50 can be regulated by the control of the flow rates in the air dampers 58. In other words, the pressure of the clean air within the transfer chamber 50 conventionally controlled depending on the flow rate in the cleaning unit 61 can be regulated at the exhaust side by installing the air dampers 58 in the air routes.

(v) With present embodiment, a local down-stream airflow of clean air is formed near the wafer entry and exit gate 51 by the second cleaning unit 56. This makes it possible to prevent the air from staying in the corner area near the wafer entry and exit gate 51 even when the space for installation of an exhaust unit is hard to secure in that corner area. This is quite effective in suppressing particle contamination of the wafers conveyed through the wafer entry and exit gate 51.

(vi) In the present embodiment, when the exhaust units 53a and 53b are installed in the corner areas within the transfer chamber 50, the flow rate in the cleaning unit 52 and the total flow rate in the exhaust units 53a and 53b are balanced so that they can be equal to each other. This makes it possible to form well-balanced airflow.

### Other Embodiments of the Present Disclosure

Next, a description will be made on other embodiments of the present disclosure.

While the two-boat-type substrate processing apparatus is taken as an example in the embodiment described above, the present disclosure is not limited thereto. Needless to say, the present disclosure is applicable to a so-called one-boat-type substrate processing apparatus in which a single boat 30 is loaded into and unloaded from a processing chamber 42.

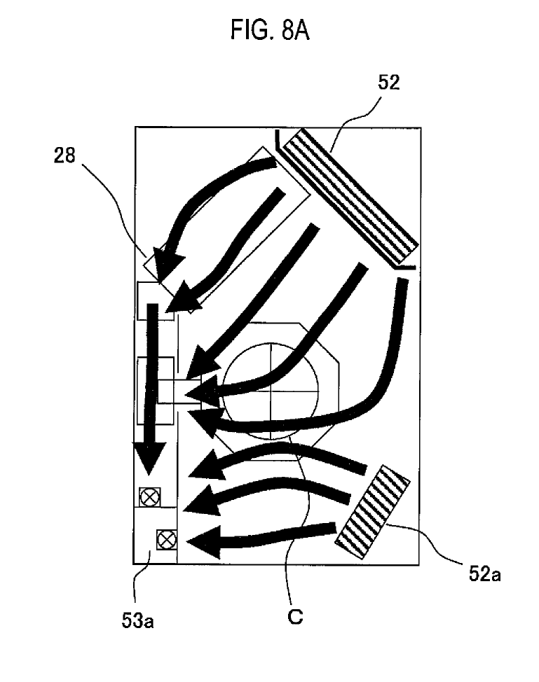

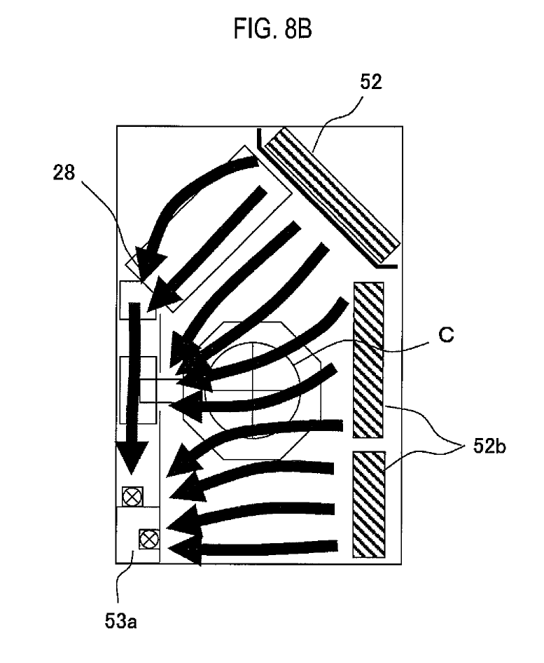

FIGS. 8A and 8B are plan views showing certain examples of airflow formation within a transfer chamber of a substrate processing apparatus according to another embodiment of the present disclosure.

In the illustrated examples, airflow is formed within a transfer chamber 50 of a one-boat-type substrate processing apparatus. As compared with the two-boat-type substrate processing apparatus, the one-boat-type substrate processing apparatus includes a reduced number of components arranged within the transfer chamber 50. This means that an extra space is available in the transfer chamber 50.

The extra space is utilized when the present disclosure is applied to the one-boat-type substrate processing apparatus. As shown in FIG. 8A, one of the exhaust units 53a and 53b otherwise arranged in the corner area within the transfer chamber 50 may be replaced by an additional cleaning unit 52a so that airflow can be formed from two spots within the transfer chamber 50. In other words, the additional cleaning unit 52a is arranged in the corner area other than the corner area where the cleaning unit 52 exists. Thus, the cleaning units 52 and 52a are used in combination. This makes it possible to form steady (well-ordered) side-to-side airflow near the boat 30 within the transfer chamber 50 while restraining the air from staying in the corner areas.

As shown in FIG. 8B, additional cleaning units 52b other than the cleaning unit 52 may be arranged side by side along one sidewall of the transfer chamber 50 (along one side of transfer chamber 50 having a rectangular plan-view shape). In this case, the cleaning units 52 and 52b are used in combination. This makes it possible to form steady (well-ordered) side-to-side airflow near the boat 30 within the transfer chamber 50 while preventing the air from staying in the corner areas.

As described above, the combined use of the cleaning unit 52 and the additional cleaning units 52a, 52b makes it possible to generate steady side-to-side airflow near the boat 30. This assists in maintaining the cleanliness of the wafers 14 held in the boat 30.

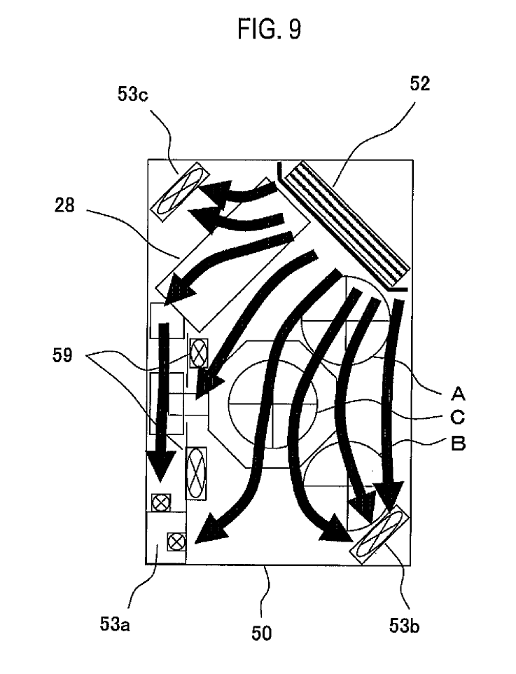

FIG. 9 is a plan view showing an example of airflow formation within a transfer chamber of a substrate processing apparatus according to a further embodiment of the present disclosure.

In the illustrated example, airflow is formed within a transfer chamber 50 of a two-boat-type substrate processing apparatus. It goes without saying that the present embodiment is equally applicable to a one-boat-type substrate processing apparatus.

In the configuration example shown in FIG. 9, local exhaust units 59 for local exhaust of clean air to an airflow circulation path 55 are provided at specific points on a clean air route within a transfer chamber 50. Examples of the specific points include a point where a difficulty may be encountered in properly maintaining the environment within the transfer chamber 50 (e.g., the cleanliness or the temperature), such as a point where a temperature rise is likely to occur. No particular restriction is imposed on the number of the specific points. If the air existing within the transfer chamber 50 is allowed to flow toward the airflow circulation path 55 through the local exhaust units 59 installed at the specific points, it becomes easy to properly maintain the environment within the transfer chamber 50 as compared with a case where the local exhaust units 59 are absent.

With the configuration having the local exhaust units 59, it is possible to properly maintain the environment within the transfer chamber 50. This makes it possible to maintain the cleanliness of the wafers 14 at a high level and to provide a sufficient cooling effect with respect to the wafers 14.

In the configuration example shown in FIG. 9, an exhaust unit 53c is further provided in the corner area near the wafer entry and exit gate 51. As long as an installation space is available, it is desirable to install the exhaust unit 53c. This makes it possible to reliably prevent the air from staying in the corner area near the wafer entry and exit gate 51.

Needless to say, the present disclosure is not limited to the foregoing embodiments but may be modified in many different forms without departing from the scope of the present disclosure defined in the claims.

### <Aspects of the Present Disclosure>

Hereinafter, aspects of the present disclosure will be additionally stated.

One aspect of the present disclosure is directed to a substrate processing apparatus, including: a processing chamber in which a substrate is processed; a substrate holder configured to be loaded into and unloaded from the processing chamber while holding the substrate; a transfer chamber in which a charging operation for causing the substrate holder to hold an unprocessed substrate and a discharging operation for taking out a processed substrate from the substrate holder are performed; and a cleaning unit configured to blow clean air into the transfer chamber, the transfer chamber having a polygonal plan-view shape and including corner areas, the cleaning unit arranged in one of the corner areas of the transfer chamber.

The apparatus according to one aspect may further include: an exhaust unit configured to exhaust therethrough the air existing within the transfer chamber, the exhaust unit arranged in a corner area within the transfer chamber other than the corner area where the cleaning unit is arranged.

The apparatus according to another aspect may further include: an air diffuser configured to distribute the clean air blown out from the cleaning unit in at least three different directions.

The apparatus according to yet another aspect may further include: an airflow circulation path through which the air exhausted from the transfer chamber is resupplied into the transfer chamber through the cleaning unit; and an air damper configured to control a flow rate of the air flowing through the airflow circulation path, the air damper configured to regulate a pressure of the air supplied into the transfer chamber by controlling the flow rate of the air.

The apparatus according to another aspect may further include: a second cleaning unit configured to generate a local down-stream airflow of the clean air near a substrate receiving communication gate within the transfer chamber

In the apparatus according to yet another aspect, the exhaust unit may include a plurality of exhaust units arranged in the corner areas within the transfer chamber, the total flow rate in the exhaust units and the flow rate in the cleaning unit being balanced to become equal to each other.

The apparatus according to an additional aspect may further include: an additional cleaning unit arranged either in the corner area other than the corner area where the cleaning unit is arranged or in a position along one sidewall of the transfer chamber having the polygonal plan-view shape so that the cleaning unit and the additional cleaning unit can be used in combination.

The apparatus according to another aspect may further include: a local exhaust unit provided in a specific point on a clean air route within the transfer chamber to perform local exhaust of the air to the airflow circulation path.

Another aspect of the present disclosure is directed to a substrate processing apparatus, including: a processing chamber in which a substrate is processed; a substrate holder configured to be loaded into and unloaded from the processing chamber while holding the substrate; a transfer chamber in which a charging operation for causing the substrate holder to hold an unprocessed substrate and a discharging operation for taking out a processed substrate from the substrate holder are performed; and a cleaning unit configured to blow clean air into the transfer chamber, the transfer chamber having a polygonal plan-view shape, the cleaning unit arranged to generate a stream of the clean air at least in a diagonal direction of the transfer chamber having the polygonal plan-view shape.

A further aspect of the present disclosure is directed to a method of manufacturing a semiconductor device, including: a pre-loading transfer step of performing, within a transfer chamber in communication with a processing chamber, a charging operation by which a substrate holder is caused to hold an unprocessed substrate before the substrate holder is loaded into the processing chamber; loading the substrate holder holding the unprocessed substrate from the transfer chamber into the processing chamber; processing the substrate held by the substrate holder loaded into the processing chamber; unloading the substrate holder holding a processed substrate from processing chamber into the transfer chamber; and a post-loading transfer step of performing a discharging operation by which the processed substrate held by the substrate holder unloaded from the processing chamber is taken out from the substrate holder, wherein clean air is blown into the transfer chamber by a cleaning unit during at least one of the pre-loading transfer step and the post-loading transfer step, the transfer chamber configured to have a polygonal plan-view shape, the cleaning unit arranged in a corner area of the transfer chamber.

According to the present disclosure, the cleaning unit is arranged in one of the corner areas within the transfer chamber so that the cleaning unit can blow a clean air from the one corner area toward the remaining corner areas. Accordingly, the air is prevented from staying within the transfer chamber (particularly in the respective corner areas), which makes it possible to form airflow in a reliable manner. In other words, even when the substrates taken out from the processing chamber emit heat, it is possible to prevent the substrates from being contaminated with particles. This is because the present embodiment is configured to prevent air from not flowing which may cause wafers to be contaminated with particles. Moreover, the installation of the cleaning unit in the corner area within the transfer chamber makes it possible to efficiently use the space within the transfer chamber and to readily reduce the installation space of the substrate processing apparatus as compared with the conventional configuration (e.g., side-to-side airflow). That is to say, it is possible to realize a configuration that can keep the apparatus width as small as possible even when the substrates have an increased size.

While certain embodiments have been described, these embodiments have been presented by way of example only, and are not intended to limit the scope of the disclosures. Indeed, the novel apparatus and method described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing chamber in which a substrate is processed;
a substrate holder configured to be loaded into and unloaded from the processing chamber while holding the substrate;
a transfer chamber in which a charging operation for causing the substrate holder to hold an unprocessed substrate and a discharging operation for taking out a processed substrate from the substrate holder are performed; and
a cleaning unit configured to blow clean air into the transfer chamber, wherein the transfer chamber has a polygonal plan-view shape and the cleaning unit is arranged in a first corner area of the transfer chamber.

2. The apparatus of claim 1, further comprising:
an exhaust unit configured to exhaust therethrough air existing within the transfer chamber, the exhaust unit arranged in a second corner area of the transfer chamber.

3. The apparatus of claim 1, further comprising:
an air diffuser configured to distribute the clean air blown out from the cleaning unit in at least three different directions.

4. The apparatus of claim 1, further comprising:
an airflow circulation path through which the air exhausted from the transfer chamber is resupplied into the transfer chamber through the cleaning unit; and
an air damper configured to control a flow rate of the air flowing through the airflow circulation path, the air damper configured to regulate a pressure of the air supplied into the transfer chamber by controlling the flow rate of the air.

5. A method of manufacturing a semiconductor device, the method comprising:
a pre-loading transfer operation of performing, within a transfer chamber in communication with a processing chamber, a charging operation by which a substrate holder is caused to hold an unprocessed substrate before the substrate holder is loaded into the processing chamber;
loading the substrate holder holding the unprocessed substrate from the transfer chamber into the processing chamber;
processing the substrate held by the substrate holder loaded into the processing chamber;
unloading the substrate holder holding a processed substrate from the processing chamber into the transfer chamber; and
a post-loading transfer operation of performing a discharging operation by which the processed substrate held by the substrate holder unloaded from the processing chamber is taken out from the substrate holder,
wherein clean air is blown into the transfer chamber by a cleaning unit during at least one of the pre-loading transfer operation and the post-loading transfer operation, the transfer chamber configured to have a polygonal plan-view shape, the cleaning unit arranged in a corner area of the transfer chamber.
